(19) United States
(12) Patent Application Publication
(10) Pub. No.: US 2024/0283222 A1
(43) Pub. Date: Aug. 22, 2024

(54) LIGHT EMITTING DEVICE, LASER PROCESSING SYSTEM, METHOD FOR MANUFACTURING LIGHT EMITTING DEVICE, AND METHOD FOR MANUFACTURING LASER PROCESSING SYSTEM

(71) Applicant: Panasonic Holdings Corporation, Osaka (JP)

(72) Inventors: TAKAYUKI KAI, Kyoto (JP); HIROSHI OHNO, Osaka (JP); KOUJI OOMORI, Shiga (JP)

(21) Appl. No.: 18/635,025

(22) Filed: Apr. 15, 2024

Related U.S. Application Data
(63) Continuation of application No. PCT/JP2022/034735, filed on Sep. 16, 2022.

(30) Foreign Application Priority Data
Oct. 27, 2021 (JP) 2021-175706

(51) Int. Cl. H01S 5/40; B23K 26/064; H01S 5/023; H01S 5/042; H01S 5/14

(52) U.S. Cl. CPC H01S 5/4012; B23K 26/064; H01S 5/023; H01S 5/04256; H01S 5/143; H01S 5/4031; H01S 2301/18

(57) ABSTRACT

A light emitting device includes a first laser diode including a plurality of emitters that emit first laser beams, a second laser diode including a plurality of emitters that emit second laser beams, the second laser diode being different from the first laser diode, a first beam twister unit provided to correspond to the first laser diode, and a second beam twister unit provided to correspond to the second laser diode, the second twister unit being different from the first beam twister unit.

### TECHNICAL FIELD

The present disclosure relates to a light emitting device, a laser processing system, a method for manufacturing a light emitting device, and a method for manufacturing a laser processing system.

### BACKGROUND ART

As a technique related to a laser processing system, a wavelength beam combining (WBC) technique for condensing laser beams from a plurality of laser emission sources has been known (PTL 1 and PTL 2). A high-power laser processing system can be realized by applying the WBC technique.

The laser processing system is utilized for applications such as welding, cutting, drilling, and material processing.

A WBC laser processing system typically includes a laser diode in which a plurality of emitters that emit laser beams are disposed one-dimensionally, an optical fiber that guides the laser beams from the emitters, and an optical system that irradiates a workpiece with the laser beams guided by the optical fiber. For example, PTL 3 discloses a laser diode bar suitable for such a laser processing system.

In the laser processing system, a plurality of laser beams emitted from the plurality of emitters are condensed on a diffraction grating, then is guided into the optical fiber, and is irradiated onto the workpiece by the optical system. In this manner, processing of the workpiece with the laser beam is performed.

### CITATION LIST

### Patent Literature

PTL 1: US Patent Publication No. 2018/0198257
PTL 2: Unexamined Japanese Patent Publication No. 2015-106707
PTL 3: Unexamined Japanese Patent Publication No. 2002-335047

### SUMMARY OF THE INVENTION

A light emitting device of one aspect of the present disclosure includes a first laser diode including a plurality of emitters that emit first laser beams, a second laser diode including a plurality of emitters that emit second laser beams, the second laser diode being different from the first laser diode, a first beam twister unit provided to correspond to the first laser diode, and a second twister unit provided to correspond to the second laser diode, the second twister unit being different from the first beam twister unit.

A method for manufacturing a light emitting device of one aspect of the present disclosure includes disposing a first laser diode including a plurality of emitters that emit first laser beams, disposing a second laser diode including a plurality of emitters that emit second laser beams, the second laser diode being different from the first laser diode, disposing a first beam twister unit to correspond to the first laser diode, and disposing a second beam twister unit different from the first beam twister unit to correspond to the second laser diode.

### BRIEF DESCRIPTION OF THE DRAWINGS

FIG. 1 is a conceptual diagram of a WBC laser processing system of the related art.

FIG. 2 is a schematic view illustrating a light emitting device of the related art.

FIG. 3 is a schematic view illustrating the light emitting device of the related art when an upper electrode and a beam twister unit are removed.

FIG. 4 is a schematic view illustrating a laser diode of the related art.

FIG. 5 is a schematic view illustrating a beam twister unit included in the light emitting device of the related art.

FIG. 6 is a diagram illustrating a relationship between a deviation of laser beam on a diffraction grating and a magnitude of warpage of a laser diode.

FIG. 7 is a diagram for describing a deviation of the laser beam on the diffraction grating.

FIG. 8 is a conceptual diagram of a WBC laser processing system according to a first exemplary embodiment.

FIG. 9 is a schematic view illustrating a light emitting device according to the first exemplary embodiment.

FIG. 10 is a schematic view illustrating the light emitting device when an upper electrode and a beam twister unit are removed.

FIG. 11 is a schematic view illustrating a laser diode included in the light emitting device according to the first exemplary embodiment.

FIG. 12 is a schematic view of the light emitting device according to the first exemplary embodiment as viewed from a front surface.

FIG. 13 is a schematic view of the light emitting device according to the first exemplary embodiment as viewed from a side surface.

FIG. 14 is a diagram for describing an orientation of a beam twister unit included in the light emitting device according to the first exemplary embodiment.

FIG. 15 is a flowchart illustrating a procedure of manufacturing the light emitting device according to the first exemplary embodiment.

FIG. 16 is a diagram illustrating a state of the light emitting device during adjustment of a disposing position of the beam twister unit.

FIG. 17 is a diagram illustrating a state of the light emitting device during a fixing operation of the beam twister unit.

FIG. 18 is a diagram illustrating a state of the light emitting device during adjustment of a disposing position of the other beam twister unit.

FIG. 19 is a diagram illustrating a state of the light emitting device during a fixing operation of the other beam twister unit.

FIG. 20 is a graph representing intensity distributions of laser beams on a diffraction grating of the laser processing system.

FIG. 21 is a schematic view illustrating a light emitting device included in a laser processing system according to a second exemplary embodiment.

FIG. 22 is a schematic view illustrating the light emitting device when an upper electrode and a beam twister unit are removed.

FIG. 23 is a schematic view of the light emitting device from which the upper electrode and the beam twister unit are removed as viewed from a front surface.

FIG. 24 is a schematic view of the light emitting device as viewed from a front surface.

FIG. 25 is a diagram illustrating the vicinity of a light emitting device of a laser processing system according to a first modification.

FIG. 26 is a diagram for describing a positional relationship between optical components in the laser processing system according to the first modification.

FIG. 27 is a schematic view illustrating a light emitting device according to a second modification, and is a diagram illustrating the light emitting device when an upper electrode and a beam twister unit are removed.

### DESCRIPTION OF EMBODIMENT

### [Circumstances]

First, circumstances leading to a light emitting device, a laser processing system, a method for manufacturing a light emitting device, and a method for manufacturing a laser processing system of the present disclosure will be described.

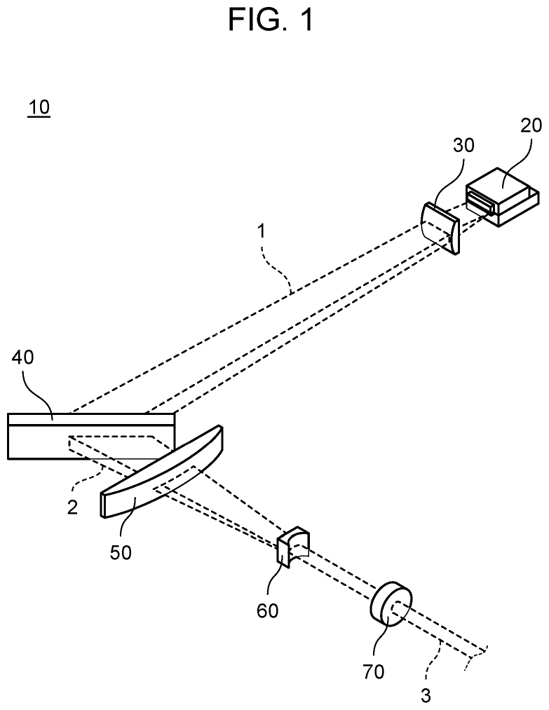

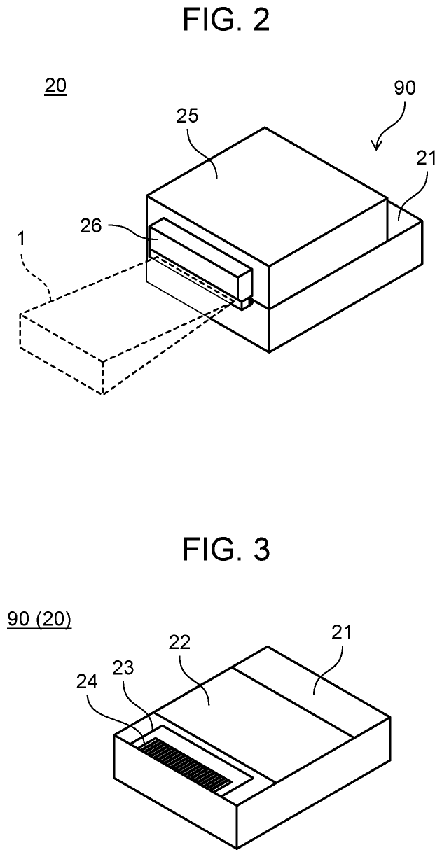

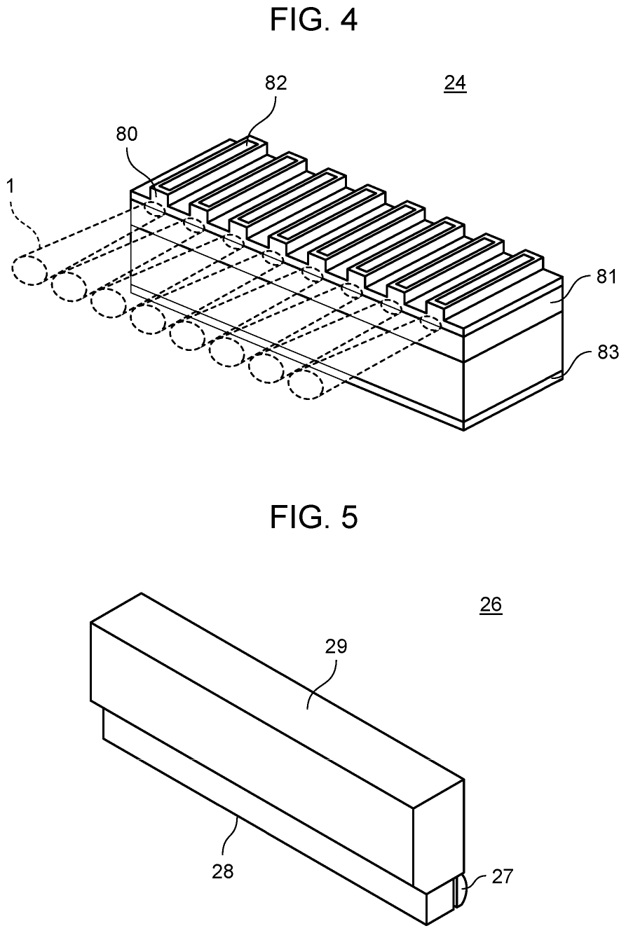

FIG. 1 is a conceptual diagram of WBC laser processing system 10 of the related art. FIG. 2 is a schematic view illustrating light emitting device 20 of the related art. FIG. 3 is a schematic view illustrating light emitting device 20 of the related art when upper electrode 25 (to be described later) and beam twister unit 26 (to be described later) are removed. FIG. 4 is a schematic view illustrating laser diode 24. FIG. 5 is a schematic view illustrating beam twister unit 26.

WBC laser processing system 10 is a system that bonds laser beams 1 having different wavelengths and emits the coupled light as output light 3.

Laser processing system 10 includes light emitting device 20, slow axis collimation (SAC) lens 30, diffraction grating 40, and external resonance half mirror 70.

In laser processing system 10, a plurality of laser beams 1 emitted from light emitting device 20 is adjusted by SAC lens 30 and the like, and is then converged on diffraction grating 40. Laser processing system 10 causes laser beam 1 to resonate between external resonance half mirror 70 and light emitting device 20 to cause laser oscillation, and irradiates toward a workpiece (not illustrated) with output light 3.

Light emitting device 20 includes laser diode module (hereinafter, referred to as an “LD module”) 90 served as an emission source of laser beam 1 and beam twister unit 26 (see FIG. 2).

As illustrated in FIGS. 2 and 3, LD module 90 includes lower electrode 21, insulating sheet 22, sub-mount 23, laser diode 24, and upper electrode 25.

Insulating sheet 22 is disposed between lower electrode 21 and upper electrode 25 in order to electrically insulate lower electrode 21 and upper electrode 25 from each other.

Sub-mount 23 is disposed on lower electrode 21 to control a temperature of laser diode 24. This temperature control includes cooling laser diode 24 whose temperature has risen due to generation of heat during the emission of laser beam 1. Laser diode 24 is cooled via lower electrode 21 and sub-mount 23 by a cooling system (not illustrated).

Laser diode 24 is a semiconductor element that emits a plurality of laser beams 1, and is disposed on sub-mount 23. In addition, as illustrated in FIG. 4, laser diode 24 includes laser emission layer 81, p-side electrode 82, and n-side electrode 83.

In order to realize a high power in laser processing system 10, a plurality of emitters 80 that emit laser beams 1 are formed in laser emission layer 81. For example, in laser emission layer 81, 48 emitters 80 are formed at a pitch of several hundred micrometers.

p-side electrode 82 and n-side electrode 83 are electrodes in an element electrically connected to lower electrode 21 and upper electrode 25, respectively. A plurality of p-side electrodes 82 are provided to correspond to emitters 80. Laser diode 24 is disposed on sub-mount 23 such that n-side electrode 83 faces lower electrode 21. In the present specification, a side of laser diode 24 on which the p-side electrode is positioned is referred to as a “p-side”, and a side on which the n-side electrode is positioned is referred to as an “n-side”.

Lower electrode 21 and upper electrode 25 are block-shaped electrodes. Lower electrode 21 electrically connects a p-side of laser diode 24 to an external power supply. Upper electrode 25 electrically connects a n-side of laser diode 24 to the external power supply. When a current flows between lower electrode 21 and upper electrode 25, the plurality of emitters 80 emit light, and each emitter 80 emits laser beam 1.

Beam twister unit 26 is disposed on a laser emission surface side of laser diode 24 (see FIG. 2). Beam twister unit 26 collimates the plurality of laser beams 1 emitted from laser diode 24 in a fast direction, and further rotates and emits the plurality of laser beams 1. Note that, rotating laser beam 1 means rotating a cross-sectional shape in a plane perpendicular to a propagation direction of laser beam 1.

As illustrated in FIG. 5, beam twister unit 26 includes fact axis collimation (FAC) lens 27, beam twister lens 28, and holding block 29.

FAC lens 27 is a lens that collimates laser beam 1 emitted from emitter 80 in the fast direction to adjust a divergence angle in the fast direction, and a plurality of FAC lenses 27 are disposed to correspond to the plurality of emitters 80, respectively. Each laser beam 1 is collimated in the fast direction by being transmitted through FAC lens 27, and a beam shape changes.

Beam twister lens 28 includes a plurality of cylindrical lenses. More specifically, the plurality of cylindrical lenses are arranged on an incident side of laser beam 1 in beam twister lens 28 to correspond to the plurality of emitters 80, respectively, and the plurality of cylindrical lenses are arranged on an emission side of laser beam 1 to correspond to the plurality of emitters 80, respectively. These cylindrical lenses are disposed at an angle of 45 degrees with respect to a fast axis.

Beam twister lens 28 is aligned such that optical axes of the plurality of cylindrical lenses coincide with emission axes of the plurality of emitters 80 of laser diode 24, respectively. The plurality of laser beams 1 transmitted through FAC lenses 27 are rotated by being transmitted through beam twister lens 28. As a result, a fast axis and a slow axis of laser beam 1 emitted from beam twister lens 28 are switched with respect to a fast axis and a slow axis of laser beam 1 before being incident on beam twister lens 28.

Holding block 29 is a member that holds FAC lens 27 and beam twister lens 28, and is bonded and fixed to upper electrode 25. As a result, a positional relationship between FAC lens 27 and beam twister lens 28 and emitter 80 of laser diode 24 is fixed.

SAC lens 30 is a lens that converges laser beam 1 transmitted through beam twister unit 26 in a slow direction and adjusts a divergence angle in the slow direction. Laser beam 1 is collimated in the slow direction by being transmitted through SAC lens 30, and the beam shape changes.

The plurality of laser beams 1 emitted from SAC lens 30 are condensed on diffraction grating 40.

Since diffraction grating 40 and light emitting device 20 are disposed such that an emission angle from diffraction grating 40 is constant and corresponds to a locked wavelength of light emitting device 20, diffraction grating 40 diffracts the plurality of laser beams 1 at different angles in accordance with the wavelengths and emits the laser beams as combined light 2.

Combined light 2 emitted from diffraction grating 40 transmits through convex lens 50 and concave lens 60, and is then incident on external resonance half mirror 70. Laser oscillation is performed by vertically reflecting a part of combined light 2 by external resonance half mirror 70 and returning to each emitter 80 of laser diode 24. As a result, output light 3 obtained by combining laser beams 1 having different wavelengths is emitted from external resonance half mirror 70. As described above, beam intensity of laser processing system 10 can be enhanced by combining laser beams 1 having different wavelengths.

In laser diode 24, it is ideal that points of emitters 80 (hereinafter, referred to as “laser emission points”) at which laser beams are emitted are arranged at the same height. However, in a case where laser diode 24 is warped, the heights of the plurality of laser emission points are deviated. Note that, a magnitude of the warpage of laser diode 24 is represented by, for example, a difference between a height of the emission point positioned closest to the p-side and a height of the emission point positioned closest to the n-side among the laser emission points of laser diode 24.

In a case where the heights of the plurality of laser emission points are different, positions of some laser emission points are deviated from an ideal position (that is, a height) with respect to FAC lens 27. As a deviation of an optical axis of laser beam 1 from an optical axis of FAC lens 27 (hereinafter, referred to as a “deviation on the FAC lens”) increases, a deviation of the optical axis of laser beam 1 from a condensing point of diffraction grating 40 (hereinafter, referred to as a “deviation on the diffraction grating”) increases in proportion to a distance from laser diode 24 to diffraction grating 40.

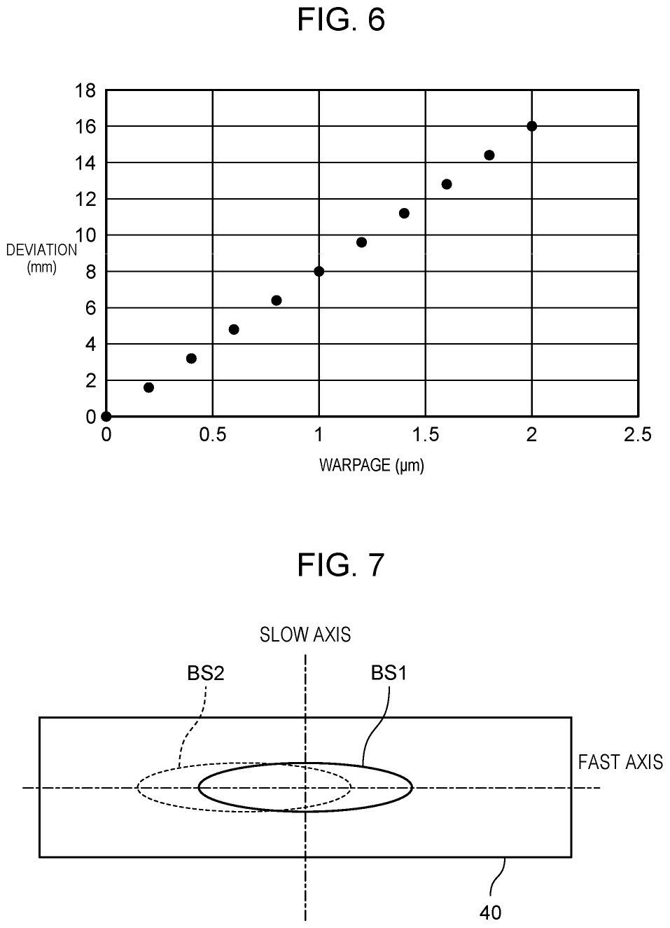

FIG. 6 is a diagram illustrating a relationship between a deviation on the diffraction grating under a predetermined condition and a magnitude of the warpage of laser diode 24. The predetermined condition is a condition in which a distance from emitter 80 to FAC lens 27 is about 30 μm and a distance from FAC lens 27 to diffraction grating 40 is 1000 mm.

For example, in a case where the warpage of laser diode 24 is 2 μm, even though a positional relationship between laser diode 24 and FAC lens 27 is determined such that the deviation on the FAC lens is minimized, the deviation on the FAC lens is 1 μm. In this case, from FIG. 6, the deviation on the diffraction grating is about 8 mm.

A size of FAC lens 27 is very small, and is about several hundred micrometers. Thus, a focal length of FAC lens 27 is small. Accordingly, only a slight deviation on the FAC lens occurs, and the deviation on the diffraction grating becomes large.

When the warpage of laser diode 24 is adjusted to be more than or equal to 0 μm and less than or equal to 2 μm, laser diode 24 has a warpage of about 2 μm at the maximum. The heights of the plurality of laser emission points vary in accordance with warpage. As a result, the optical axis of laser beam 1 emitted from each emitter 80 projected on diffraction grating 40 is deviated in the fast direction.

FIG. 7 is a diagram for describing a deviation of laser beam 1 on diffraction grating 40. A solid line indicates beam spot BS1 of laser beam 1 when the optical axis of FAC lens 27 coincides with the optical axis of laser beam 1 for each emitter 80. A broken line indicates beam spot BS2 of laser beam 1 in a case where the warpage of laser diode 24 is relatively large and a distance between the optical axis of laser beam 1 and the optical axis of FAC lens 27 is large. FIG. 7 illustrates that beam spot BS2 is deviated in the fast direction with respect to beam spot BS1.

As described above, when the optical axis of laser beam 1 is deviated in the fast direction, the overlapping of laser beams 1 on external resonance half mirror 70 deteriorates, and a beam quality of output light 3 deteriorates.

In addition, laser diode 24 is cut out in a chip shape from a semiconductor wafer. Depending on a relationship between dimensions of the semiconductor wafer and dimensions of laser diode 24, the number of laser diodes 24 capable of being cut out from one semiconductor wafer (hereinafter, referred to as an “obtainable number”) may become extremely small. For example, in a case where the number of emitters 80 disposed in one laser diode 24 is increased to increase a laser output of laser processing system 10, the dimension of laser diode 24 in a direction in which the emitters 80 are arrayed is increased. In this case, there is a concern that the obtainable number decreases.

Further, when the number of emitters 80 disposed in laser diode 24 is increased, since a possibility that a defective emitter is included in laser diode 24 is increased, a yield rate of laser diode 24 is exponentially deteriorated in accordance with the number of emitters 80.

As described above, when the number of emitters built in the laser diode is increased in order to increase the power of the laser processing system, a length of the laser diode becomes long, and warpage easily occurs. When the laser diode is warped, the plurality of emitters are not arrayed one-dimensionally and are not positioned at the same height. In this case, the laser beam is not condensed at a desired position, and the beam quality of the laser processing system deteriorates.

Therefore, in view of the above-described problems, the inventor of the present invention has invented a light emitting device, a laser processing system, a method for manufacturing a light emitting device, and a method for manufacturing a laser processing system of the present disclosure. According to the light emitting device, the laser processing system, the method for manufacturing a light emitting device, and the method for manufacturing a laser processing system of the present disclosure, the beam quality can be improved.

In addition, the yield rate of laser diode 24 can be improved. Further, according to an exemplary embodiment of the light emitting device, the laser processing system, the method for manufacturing a light emitting device, and the method for manufacturing a laser processing system of the present disclosure, the semiconductor wafer can be effectively used.

An object of the present disclosure is to provide a light emitting device, a laser processing system, a method for manufacturing a light emitting device, and a method for manufacturing a laser processing system capable of improving beam quality.

Hereinafter, a light emitting device, a laser processing system, a method for manufacturing a light emitting device, and a method for manufacturing a laser processing system of the present disclosure will be described in detail with reference to the drawings. In exemplary embodiments to be described below, numerical values, shapes, materials, constituent elements, disposing positions of the constituent elements, connection forms, steps, order of the steps, and the like are merely examples, and there is no intention to limit the present disclosure. Thus, among the constituent elements in the following exemplary embodiments, constituent elements that are not described in independent claims indicating a highest concept of the present disclosure are described as optional constituent elements.

In addition, the drawings are schematic views, and are not strictly illustrated. Accordingly, scales and the like in the drawings do not necessarily coincide with each other. In the drawings, substantially identical configurations are denoted by identical reference marks, and redundant description will be omitted or simplified.

### First Exemplary Embodiment

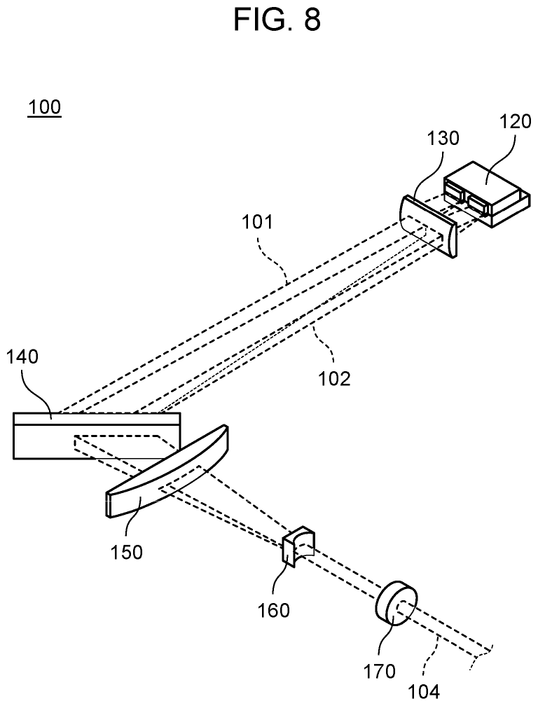

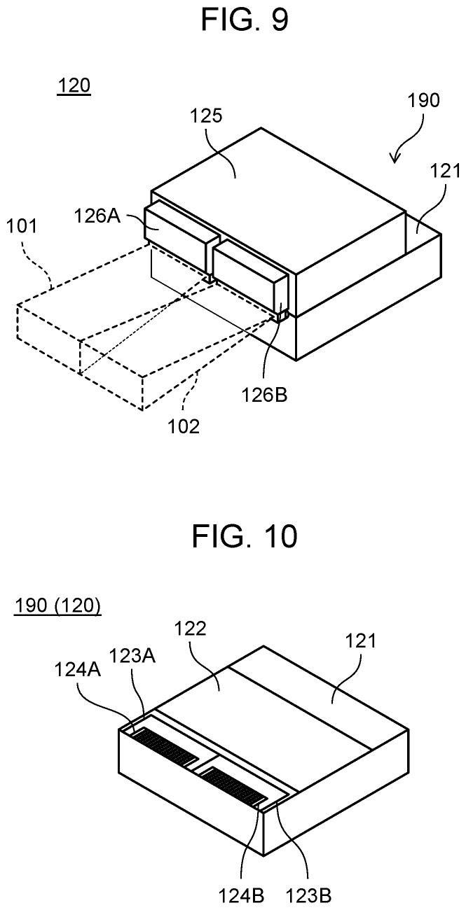

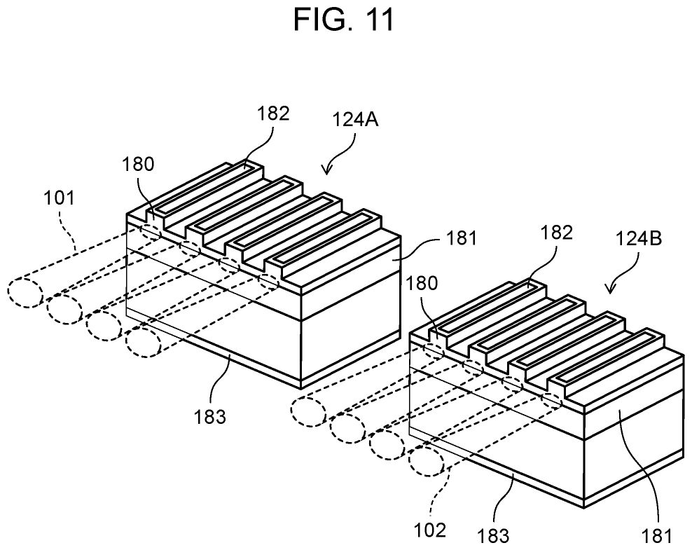

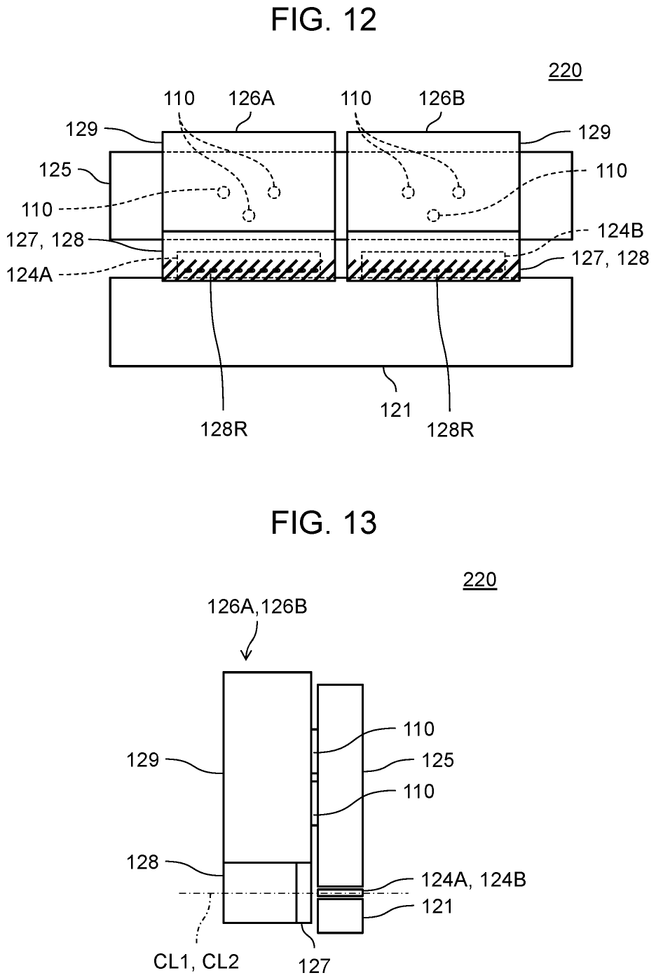

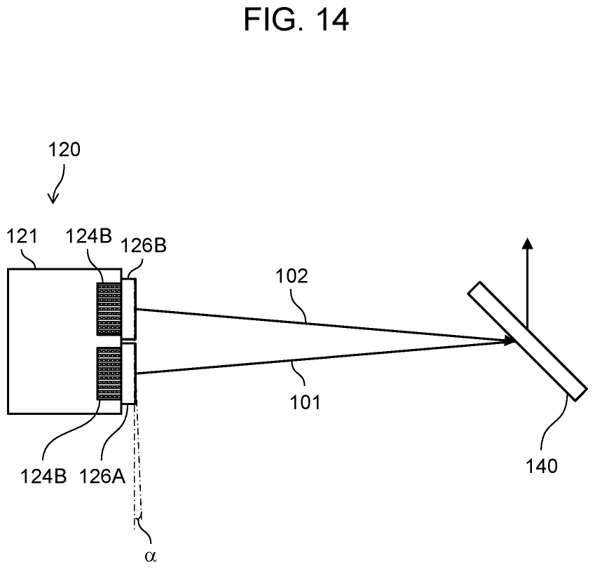

FIG. 8 is a conceptual diagram of WBC laser processing system 100 according to the present exemplary embodiment. FIG. 9 is a schematic view illustrating light emitting device 120. FIG. 10 is a schematic view illustrating light emitting device 120 when upper electrode 125 (to be described later) and beam twister units 126A and 126B (to be described later) are removed. FIG. 11 is a schematic view illustrating laser diodes 124A and 124B. FIG. 12 is a schematic view of light emitting device 120 as viewed from a front surface. FIG. 13 is a schematic view of light emitting device 120 as viewed from a side surface. FIG. 14 is a diagram for describing orientations of beam twister units 126A and 126B.

Laser processing system 100 includes light emitting device 120, SAC lens 130, diffraction grating 140, and external resonance half mirror 170. Light emitting device 120, SAC lens 130, diffraction grating 140, and external resonance half mirror 170 are disposed in this order from an upstream side in a traveling direction of the laser beam.

Convex lens 150 and concave lens 160 may be disposed between diffraction grating 140 and external resonance half mirror 170.

An emission principle of output light 104 of laser processing system 100 is similar to an emission principle of output light 3 of laser processing system 10 of the related art described above. A difference between laser processing system 100 according to the present exemplary embodiment and laser processing system 10 of the related art is a structure of the light emitting device.

### (Light Emitting Device)

As illustrated in FIG. 9, light emitting device 120 includes LD module 190 that emits laser beams 101 and 102, first beam twister unit 126A, and second beam twister unit 126B.

As illustrated in FIGS. 9 and 10, LD module 190 includes lower electrode 121, insulating sheet 122, first sub-mount 123A, second sub-mount 123B, first laser diode 124A, second laser diode 124B, and upper electrode 125.

Insulating sheet 122 is disposed between lower electrode 121 and upper electrode 125 in order to electrically insulate lower electrode 121 and upper electrode 125 from each other.

First sub-mount 123A and second sub-mount 123B are members different from each other, and are provided to correspond to first laser diode 124A and second laser diode 124B, respectively. Similarly to sub-mount 23 described above, sub-mounts 123A and 123B are disposed on lower electrode 121 in order to control a temperature of respective laser diodes 124A and 124B. Second sub-mount 123B is independent of and separated from first sub-mount 123A.

First laser diode 124A and second laser diode 124B are semiconductor elements. Second laser diode 124B is an element different from first laser diode 124A having a structure identical to a structure of first laser diode 124A. First laser diode 124A and second laser diode 124B are disposed on first sub-mount 123A and second sub-mount 123B, respectively.

Hereinafter, a configuration of first laser diode 124A will be described. Since a configuration of second laser diode 124B is the same as the configuration of first laser diode 124A, description thereof will be omitted.

As illustrated in FIG. 11, first laser diode 124A includes laser emission layer 181, p-side electrode 182, and n-side electrode 183. Laser emission layer 181 is a layer that emits first laser beam 101. In laser emission layer 181, a plurality of emitters 180 that emit first laser beams 101 are formed at a pitch of, for example, several hundred micrometers.

The number of emitters 180 formed in laser emission layer 181 is smaller than the number of emitters 80 formed in laser diode 24 of the related art used in laser processing system 10 having a laser output equivalent to the laser output of laser processing system 100, and is for example, 35. Thus, a dimension of first laser diode 124A is shorter than the dimension of laser diode 24 of the related art in the array direction of the emitters. Note that, the number of emitters 180 formed in laser emission layer 181 may be more than or equal to 2, and for example, two or more emitters 180 may be formed at a pitch of several hundred micrometers.

p-side electrode 182 and n-side electrode 183 are electrodes in an element electrically connected to lower electrode 121 and upper electrode 125, respectively, and are the same as p-side electrode 82 and n-side electrode 83 described above.

First laser diode 124A and second laser diode 124B are disposed on first sub-mount 123A and second sub-mount 123B, respectively, such that laser emission surfaces thereof are flush with each other and n-side electrode 183 faces lower electrode 121 side.

Note that, first laser diode 124A and second laser diode 124B may be disposed such that p-side electrode 182 faces lower electrode 121 side. In the following description, an example in which first laser diode 124A and second laser diode 124B are disposed such that n-side electrode 183 faces lower electrode 121 side will be described.

Lower electrode 121 and upper electrode 125 are block-shaped electrodes that electrically connect the p-sides and the n-sides of laser diodes 124A and 125B to an external power supply, respectively.

In light emitting device 120, first laser diode 124A, first sub-mount 123A, and lower electrode 121 can be conducted without a current loss. Similarly, second laser diode 124B, second sub-mount 123B, and lower electrode 121 can be conducted without a current loss. In addition, when first laser diode 124A and second laser diode 124B are electrically conducted, polarities thereof face the same direction. Thus, in a case where a current flows between lower electrode 121 and upper electrode 125, the current flows in parallel to laser diodes 124A and 125B.

That is, the current flows between lower electrode 121 and upper electrode 125, and thus, the current flows in parallel to all emitters 180 of laser diodes 124A and 124B. When a current of a certain value or more flows through emitters 180, laser beams 101 and 102 emit light and are emitted from emitters 180.

The warpage of first laser diode 124A and second laser diode 124B is within 3.0 μm, desirably within 2.0 μm. This warpage will be described in detail later.

First beam twister unit 126A and second beam twister unit 126B are components different from each other, and are provided to correspond to first laser diode 124A and second laser diode 124B, respectively. Second beam twister unit 126B is independent of and separated from first beam twister unit 126A.

As illustrated in FIGS. 12 and 13, first beam twister unit 126A includes FAC lens 127, beam twister lens 128, and holding block 129. Similarly to FAC lens 27 described above, FAC lens 127 is a lens that collimates laser beam 101 in a fast direction and adjusts a divergence angle in the fast direction, and a plurality of FAC lenses 127 are disposed to correspond to a plurality of emitters 180, respectively.

In the present exemplary embodiment, a lens having a focal length more than or equal to 30 μm and less than or equal to 50 μm is used as FAC lens 127. This focal length will be described in detail later.

Similarly to beam twister lens 28 described above, beam twister lens 128 includes a plurality of cylindrical lenses 128R. The plurality of cylindrical lenses 128R are arranged on an incident side of laser beams 101 and 102 in beam twister lens 128 to correspond to the plurality of emitters 180, respectively, and the plurality of cylindrical lenses 128R are arranged on an emission side of laser beams 101 and 102 to correspond to the plurality of emitters 180, respectively (see FIG. 12). These cylindrical lenses 128R are disposed to be inclined at 45 degrees with respect to a fast axis.

Holding block 129 is a member that holds FAC lens 127 and beam twister lens 128, and is fixed to upper electrode 125 with adhesive 110. As a result, a positional relationship between FAC lens 127 and beam twister lens 128 and emitter 180 of laser diode 124A is fixed.

First beam twister unit 126A is disposed such that one cylindrical lens 128R is positioned for each emitter 180. Specifically, optical axis CL1 of each emitter 180 of first laser diode 124A and optical axis CL2 of each cylindrical lens 128R are aligned to coincide with each other.

A configuration of second beam twister unit 126B is the same as a configuration of first beam twister unit 126A. In addition, a positional relationship between second beam twister unit 126B and second laser diode 124B is the same as a positional relationship between first beam twister unit 126A and first laser diode 124A. Thus, detailed description thereof will be omitted.

Beam twister units 126A and 126B are disposed such that a plurality of first laser beams 101 emitted from beam twister unit 126A and a plurality of second laser beams 102 emitted from beam twister unit 126B are directed to the same position on diffraction grating 140. For example, as illustrated in FIG. 14, beam twister units 126A and 126B are disposed such that laser emission surfaces of beam twister units 126A and 126B are not parallel to each other. Note that, a in FIG. 14 is an angle formed by the laser emission surface of second beam twister unit 126B with respect to the laser emission surface of first beam twister unit 126A.

As described above, laser diodes 124A and 124B are disposed such that the laser emission surfaces are flush with each other. Orientations of beam twister units 126A and 126B are adjusted, and thus, emission directions of first laser beam 101 and second laser beam 102 from beam twister units 126A and 126B can be adjusted.

### (Warpage of Laser Diode and Dimension in Array Direction)

The warpage of first laser diode 124A and second laser diode 124B occurs, for example, due to generation of stress caused by a layer structure of a quantum well structure in laser emission layer 181.

In a case where dimensions of laser diodes 124A and 124B in the array direction of emitters 180 are 10 mm, and 2 μm and U-shaped warpage (so-called smile) occurs in laser diodes 124A and 124B, a radius of curvature of the warpage is about 6253 mm.

In addition, even though the positional relationship between each FAC lens 127 of beam twister units 126A and 126B and laser diodes 124A and 124B is adjusted, a deviation between optical axes of first laser beam 101 and second laser beam 102 and an optical axis (central axis) of FAC lens 127 is 1 μm at the maximum.

In a case where the dimensions of emitters 180 of laser diodes 124A and 124B in the array direction is 7.5 mm and laser diodes 124A and 124B are warped to have a radius of curvature of 6253 m, the warpage is 1.1 μm. Thus, the deviation between the optical axes of first laser beam 101 and second laser beam 102 and the optical axis (central axis) of FAC lens 127 is 0.55 μm at the maximum.

As described above, in a case where warpage having the same radius of curvature occurs, the shorter the dimensions of laser diodes 124A and 124B in the array direction, the smaller the warpage. As a result, when a positional relationship between beam twister units 126A and 126B and laser diodes 124A and 124B is adjusted, the deviation between the optical axes of first laser beam 101 and second laser beam 102 and the optical axis (center axis) of FAC lens 127 becomes small.

Note that, in addition to the U-shaped warpage, the warpage includes an S-shaped warpage having one mountain and one valley, an M-shaped warpage having two mountains and one valley, a W-shaped warpage having one mountain and two valleys, and the like. Even in a case where warpage of any shape occurs, the shorter the dimensions of laser diodes 124A and 124B in the array direction, the smaller the warpage that occurs, and the smaller a difference in height between a plurality of laser emission points in the identical laser diode. As a result, the deviation between the optical axes of first laser beam 101 and second laser beam 102 and the optical axis (central axis) of FAC lens 127 becomes small.

Thus, in the present exemplary embodiment, the laser diode in the light emitting device has a divided structure, and the dimensions in the array direction are set to be shorter than the dimensions of the laser diode of the related art having an integrated structure. Accordingly, the warpage occurring in each laser diode is suppressed, and beam quality is improved.

### (Relationship Between Warpage and Focal Length of FAC Lens)

Hereinafter, an example in which laser diode 124A is a blue direct laser diode will be described.

Laser beam 101 emitted from laser diode 124A is coherent light, but a beam shape of laser beam 101 spreads until reaching diffraction grating 140 after being emitted from emitter 180. In a case where diffraction grating 140 is disposed at a position 1000 mm away from laser diode 124A, a beam diameter of laser beam 101 is about 30 mm on diffraction grating 140.

Here, the beam diameter will be described. In a case where the laser diode includes one emitter (so-called single mode laser diode), a light intensity distribution of the laser beam emitted from the laser diode is a Gaussian distribution. The beam diameter means a diameter of a beam in a range (that is, a range of ±σ from a peak position when a standard deviation of the intensity distribution is σ) in which an intensity ratio from a peak of the intensity distribution is more than or equal to 13.5%.

On the diffraction grating, a M2 parameter of a laser beam emitted from the single mode laser diode is 1. On the other hand, a M2 parameter of combined light of a plurality of laser beams emitted from the laser diode including the plurality of emitters is larger than 1. For example, in a case where the laser diode is warped by 2 μm, the M2 parameter is more than or equal to 2.

In laser processing system 100, lens curvature of FAC lens 127 is selected in accordance with an interval between emitters 180 of laser diodes 124A and 124B.

The beam diameters of laser beams 101 and 102 emitted from emitters 180 increase before the laser beams are incident on FAC lenses 127. In a case where the divergence angle in the fast direction is 50°, in order to cause laser beams 101 and 102 to be incident on beam twister lens 128, it is necessary to adopt a FAC lens of which a focal length is more than or equal to 30 μm and less than or equal to 50 μm as FAC lens 127.

In a case where FAC lens 127 of which a focal length is more than or equal to 30 μm and less than or equal to 50 μm is adopted, in order to set a M2 parameter on diffraction grating 140 disposed at a position 1000 mm away from laser diodes 124A and 124B to be less than or equal to 4, it is necessary to set the warpage of laser diodes 124A and 124B to be less than or equal to 3.0 μm, desirably less than or equal to 2.0 μm.

In the present exemplary embodiment, since the dimensions of laser diodes 124A and 124B in the array direction are shorter than the dimensions of laser diode 24 of the related art, the warpage is easily suppressed to be less than or equal to 3.0 μm.

### (Manufacturing Method)

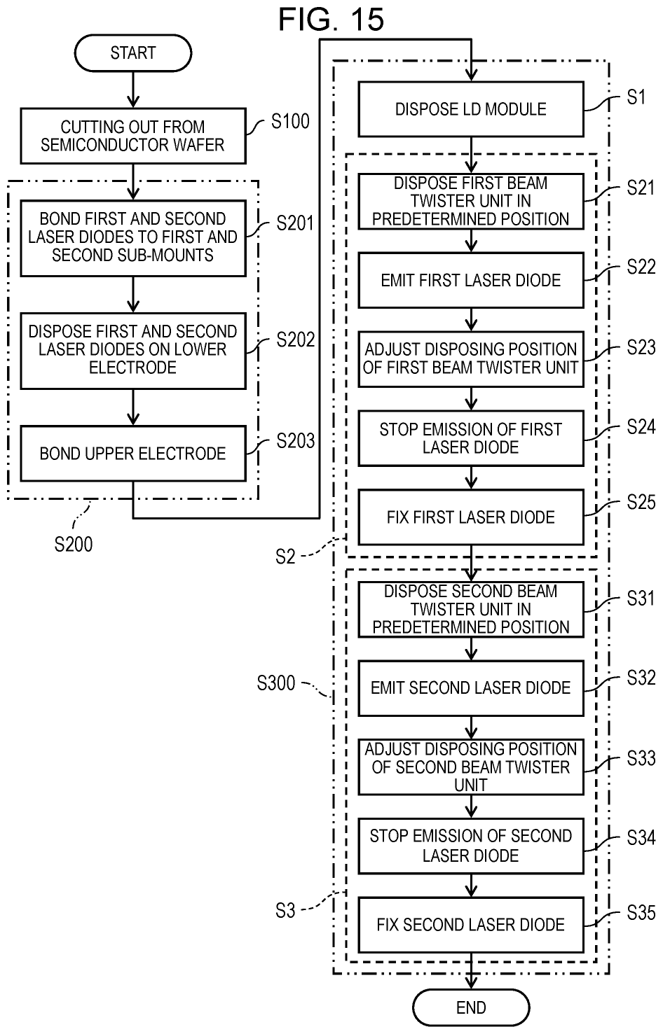

An example in which the light emitting device is manufactured by using a semiconductor wafer generated through an exposure step by stepper exposure is used in a method for manufacturing light emitting device 120 will be described with reference to FIG. 15. FIG. 15 is a flowchart illustrating a step of manufacturing light emitting device 120 according to the present exemplary embodiment.

The method for manufacturing light emitting device 120 includes (1) step S100 of cutting out laser diodes 124A and 124B from the semiconductor wafer, (2) step S200 of assembling LD module 190, and (3) step S300 of disposing beam twister units 126A and 126B.

### (1) Step S100 of Cutting Out Laser Diodes

In step S100, laser diodes 124A and 124B are cut out from the semiconductor wafer. Here, the dimensions of laser diodes 124A and 124B of emitters 180 in the array direction (hereinafter, simply referred to as “dimensions in the array direction”) are set to predetermined dimension X0.

When Y is a quotient obtained by dividing a dimension of a moiety to be cut out of the semiconductor wafer (hereinafter, referred to as a “cut-out target moiety”) by an integer N of 4 or more, predetermined dimension X0 satisfies a relational expression of Y≥X0≥0.8Y.

The cut-out target moiety is a moiety of the semiconductor wafer excluding a moiety that is held by an arm or the like when the semiconductor wafer is conveyed in a procedure of processing and cannot be cut out. The moiety that cannot be cut out is, for example, a moiety about 2 mm inward from a peripheral edge of the semiconductor wafer.

For example, in a case where laser diodes 124A and 124B are blue direct diodes, a semiconductor wafer having a diameter of 2 inches (diameter of 50 mm) is generally used. In this case, the dimension of the cut-out target moiety is 46 mm (50 mm−2 mm×2).

As a specific example, when N is set to 4, predetermined dimension X0 is 11.5 mm (46 mm÷4)≥X0≥9.2 mm (46 mm÷4×0.8), and when N is set to 5, predetermined dimension X0 is 9.2 mm (46 mm÷5)≥X0≥7.3 mm (46 mm÷5×0.8) (rounded down to a second decimal place).

Note that, a reason why a lower limit of predetermined dimension X0 is set to 80% of Y is that it is assumed that some gap is generated between exposure ranges of the stepper exposure.

### (2) Step S200 of Assembling LD Module

Step S200 of assembling LD module 190 includes step S201 of bonding laser diodes 124A and 124B onto sub-mounts 123A and 123B, respectively, step S202 of disposing laser diodes 124A and 124B on lower electrode 121, and step S203 of bonding upper electrode 125.

First, laser diodes 124A and 124B are disposed on sub-mounts 123A and 123B such that the n-sides face sub-mounts 123A and 123B, and are bonded by soldering (step S201). Subsequently, laser diodes 124A and 124B are disposed and bonded on lower electrode 121 such that sub-mounts 123A and 123B are in contact with lower electrode 121 (step S202).

Subsequently, insulating sheet 122 is bonded onto lower electrode 121, electrical connection portions such as bumps are formed on laser diodes 124A and 124B, and upper electrode 125 is bonded onto the electrical connection portions (step S203).

### (3) Step S300 of Disposing Beam Twister Units 126A and 126B

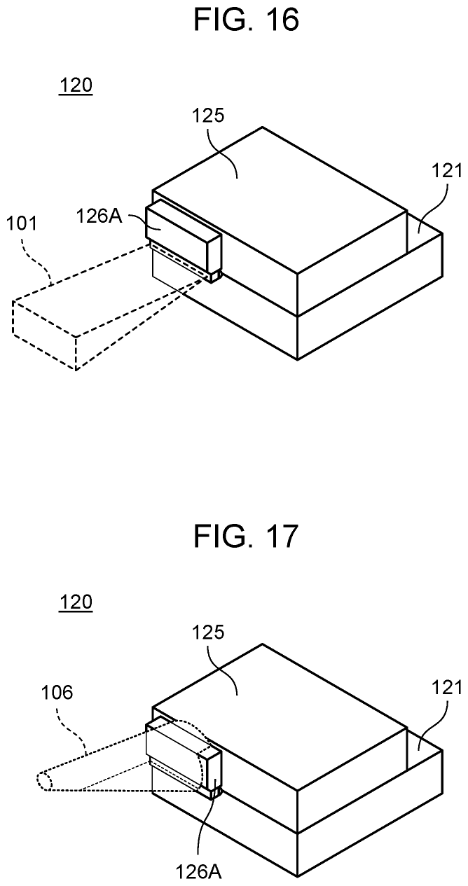

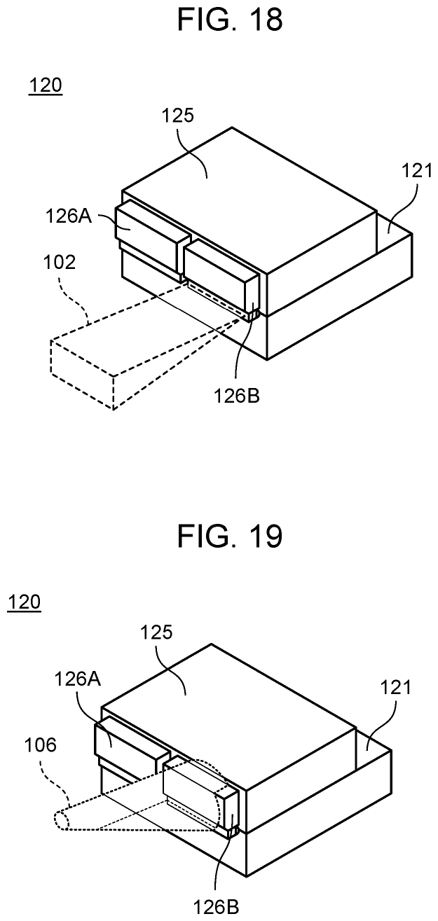

In addition to FIG. 15, step S300 of disposing beam twister units 126A and 126B will be described in detail with reference to FIGS. 16 to 19. FIG. 16 is a diagram illustrating a state of light emitting device 120 during the adjustment of the disposing position of first beam twister unit 126A. FIG. 17 is a diagram illustrating a state of light emitting device 120 during a fixing operation of first beam twister unit 126A. FIG. 18 is a diagram illustrating a state of light emitting device 120 during the adjustment of the disposing position of second beam twister unit 126B. FIG. 19 is a diagram illustrating a state of light emitting device 120 during a fixing operation of second beam twister unit 126B.

As illustrated in FIG. 15, step S300 includes steps S1 to S3.

First, LD module 190 is disposed (step S1).

Subsequently, first beam twister unit 126A is disposed (step S2). Step S2 includes steps S21 to S25.

First, first beam twister unit 126A is held by a holder (not illustrated) and is disposed at a predetermined position (step S21). The predetermined position is a laser emission end side of first laser diode 124A.

Subsequently, as illustrated in FIG. 16, a current flows between upper electrode 125 and lower electrode 121, and thus, emitter 180 of first laser diode 124A emit light, and first laser beam 101 is emitted (step S22). Here, second laser beam 102 is also emitted from second laser diode 124B, but second laser beam 102 is blocked by a shutter or the like in order to prevent the measurement of first laser beam 101 from being disturbed.

Subsequently, the disposing position of first beam twister unit 126A is adjusted (step S23).

Hereinafter, step S23 will be described in detail. First, a measurement camera (not illustrated) having a beam quality confirmation lens is disposed at an irradiation destination of first laser beam 101. First beam twister unit 126A is moved in an optical axis direction of first laser beam 101 and a direction perpendicular to the optical axis direction to adjust the position of first beam twister unit 126A to a position satisfying the following (A) to (C).
(A) A distance from emitter 180 to an incident surface of FAC lens 127 coincides with the focal length of FAC lens 127.
(B) A beam shape of the combined light becomes the smallest when the combined light based on the plurality of first laser beams 101 is viewed through the beam quality confirmation lens of the measurement camera.
(C) The plurality of first laser beams 101 are condensed at a predetermined position.

Thereafter, LD module 190 and first beam twister unit 126A are disposed in a simulated external resonance optical system. The simulated external resonance optical system is a system for preliminary measurement that imitates laser processing system 100, and includes optical components corresponding to SAC lens 130, diffraction grating 140, convex lens 150, concave lens 160, and external resonance half mirror 170.

Further, the above-described measurement camera is disposed at an irradiation destination of output light 104 emitted from the optical component corresponding to external resonance half mirror 170. The disposing position of first beam twister unit 126A is adjusted such that the intensity of output light 104 is maximized and the beam shape of output light 104 is minimized on the measurement camera.

Subsequently, the current between upper electrode 125 and lower electrode 121 is blocked, and the light emission of first laser diode 124A is stopped (step S24).

First laser diode 124A is fixed (step S25). In step S25, adhesive 110 is applied to holding block 129, and adhesive 110 is irradiated with ultraviolet ray 106 to cure adhesive 110 (see FIG. 17).

Note that, after adhesive 110 is applied, the disposing position of first beam twister unit 126A may be adjusted again by performing steps S22 to S23 again.

After the disposing position of first beam twister unit 126A is adjusted and fixed, a disposing operation of second beam twister unit 126B is performed (step S3).

Second beam twister unit 126B is disposed (step S3). Step S3 includes steps S31 to S35 corresponding to steps S21 to S25, respectively, and is the same as step S2 except that a disposing target, a position adjustment target, and a fixation target are “second beam twister unit 126 B” (see FIGS. 18 and 19).

As described above, light emitting device 120 is completed through steps $100 to S300.

Next, a method for manufacturing laser processing system 100 will be described. The method for manufacturing laser processing system 100 includes step S400 of disposing light emitting device 120 and step S500 of disposing the optical component.

First, light emitting device 120 is disposed (step S400). Subsequently, the optical components such as SAC lens 130, diffraction grating 140, convex lens 150, concave lens 160, and external resonance half mirror 170 are disposed at appropriate positions (step S500).

Through steps S400 and S500 described above, laser processing system 100 is completed.

Note that, in the present exemplary embodiment, since laser processing system 100 includes one SAC lens 130, it is not necessary to separately adjust a position of SAC lens 130 with respect to each of first beam twister unit 126A and second beam twister unit 126B.

Light emitting device 120 according to the present exemplary embodiment includes first laser diode 124A including a plurality of emitters 180 that emit first laser beam 101, second laser diode 124B including a plurality of emitters 180 that emit second laser beam 102 and being different from first laser diode 124A, first beam twister unit 126A provided to correspond to first laser diode 124A, and second beam twister unit 126B provided to correspond to second laser diode 124B and being different from first beam twister unit 126A.

The method for manufacturing light emitting device 120 according to the present exemplary embodiment includes a step (step S202) of disposing first laser diode 124A including the plurality of emitters 180 that emit first laser beam 101, a step (step S202) of disposing second laser diode 124B including the plurality of emitters 180 that emit second laser beam 102 and being different from first laser diode 124A, a step (step S2) of disposing first beam twister unit 126A to correspond to first laser diode 124A, and a step (step S3) of disposing second beam twister unit 126B different from first beam twister unit 126A to correspond to second laser diode 124B.

Thus, a structure in which a plurality of laser diodes having relatively short dimensions of emitters 180 in the array direction are disposed can be adopted as light emitting device 120 instead of laser diodes having relatively long dimensions of the emitters in the array direction. Thus, since the warpage of laser diodes 124A and 124B of light emitting device 120 can be reduced, when light emitting device 120 is adopted in laser processing system 100, the plurality of laser beams 101 and 102 can be easily condensed. As a result, the beam quality of output light 3 of laser processing system 100 can be improved.

In addition, since beam twister units 126A and 126B are disposed to correspond to laser diodes 124A and 124B, respectively, the disposing position and the orientation of the beam twister unit can be adjusted for each laser diode. Thus, condensing properties of laser beams 101 and 102 can be further enhanced, and the beam quality can be improved.

In addition, since a structure in which a plurality of laser diodes having a relatively short dimension in the array direction is arranged can be adopted as light emitting device 120, more emitters 180 can be arranged in light emitting device 120 than in the conventional light emitting device 20 without impairing the beam quality. Thus, the light output of light emitting device 120 can be increased.

More specifically, in order to suppress the magnitude of the warpage of laser diode 24, the dimension of laser diode 24 disposed in light emitting device 20 of the related art has an upper limit value. That is, there is a limit to an attempt to increase the dimension of laser diode 24 in order to dispose more emitters 80.

According to the present exemplary embodiment, since the dimensions of laser diodes 124A and 124B in the array direction are relatively short, the number of emitters 180 disposed in light emitting device 20 can be increased only by increasing the number of laser diodes disposed in light emitting device 120 without increasing the warpage of the laser diodes. As a result, a laser output value of light emitting device 120 can be increased.

In addition, since the dimensions of laser diodes 124A and 124B in the array direction can be relatively short, the number of emitters included in one laser diode is smaller than the number of emitters 80 included in laser diode 24 of the related art. Thus, a yield rate in manufacturing the laser diode can be increased.

Hereinafter, effects of (1) the beam quality improvement, (2) the improvement of the light output of the light emitting device, and (3) the improvement of the yield rate will be described with specific examples.

### (1) Beam Quality Improvement

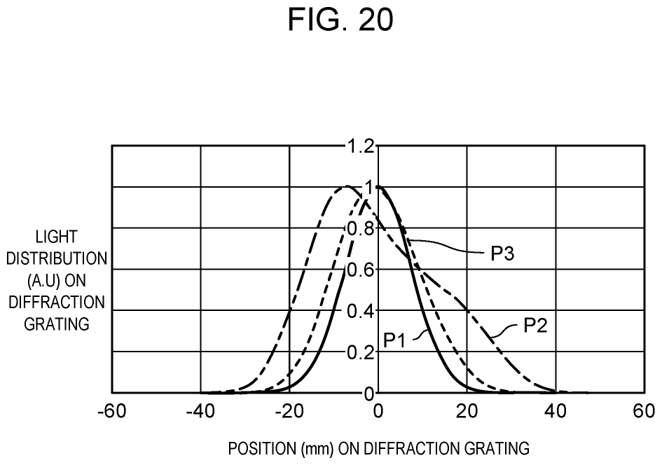

The beam quality improvement will be described with a specific example. FIG. 20 is a graph representing intensity distributions of the laser beams on the diffraction grating of the laser processing system.

P1 is an intensity distribution in a case where a light emitting device including a single mode laser diode is disposed in the laser processing system. P2 is an intensity distribution of the combined light of the plurality of laser beams 1 in a case where light emitting device 20 including laser diode 24 of the related art is disposed in the laser processing system. P3 is an intensity distribution of the combined light of the plurality of laser beams 101 and 102 in a case where light emitting device 120 including laser diodes 124A and 124B of the present exemplary embodiment is disposed in the laser processing system.

Note that, in measuring the intensity distributions in FIG. 20, warpage was set such that a radius of curvature of each of the single mode laser diode, laser diode 24 of the related art, and laser diodes 124A and 124B was 6253 mm. In addition, an average height of the laser emission point of each laser diode was matched with the height of the central axis of the FAC lens.

FIG. 20 illustrates that intensity distribution P3 has a shape closer to intensity distribution P1 than intensity distribution P2. That is, it can be said that the condensing property of the laser beam from the emitter is higher and the beam quality of the laser processing system is higher when light emitting device 120 of the present exemplary embodiment is used than light emitting device 20 of the related art.

### (2) Improvement of Light Output of Light Emitting Device

As described above, in a case where the dimensions in the array direction are increased in order to dispose a large number of emitters 80 in laser diode 24, the warpage of laser diode 24 becomes easily large. Thus, in order to suppress the magnitude of the warpage, the dimensions of laser diodes 24 in the array direction has an upper limit value. For example, when the upper limit value of the dimension of laser diode 24 in the array direction for laser diode 24 including light emitting device 20 of the related art is 10 mm, in a case where emitters 80 are disposed at a pitch of 200 μm, 48 emitters 80 can be disposed in laser diode 24.

When the light output value of laser beam 1 from each emitter 80 is 1.5 W, the light output value of laser diode 24 is 72 W (1.5 W×48).

In a case where the dimensions of laser diodes 124A and 124B included in light emitting device 120 according to the present exemplary embodiment in the array direction is set to 7.5 mm and emitters 180 are disposed at a pitch of 200 μm, 35 emitters 180 can be disposed in each of laser diodes 124A and 124B.

In a case where the light output value of laser beam 101 or 102 from each emitter 180 is 1.5 W, the light output value of light emitting device 120 is 105.0 W (1.5 W×35×2).

Thus, the laser diode has a divided structure, and thus, the number of emitters that can be disposed in one light emitting device 120 can be increased while the magnitude of the warpage is reduced as compared with a case where the integrated structure of the related art is adopted. Thus, the light output of the light emitting device can be improved while the beam quality is improved.

### (3) Improvement of Yield Rate

Hereinafter, a case where a yield rate of one emitter is 99.0% will be described. In a case where 48 emitters are disposed in the laser diode, a yield rate of the laser diode is 61% (0.99⁴⁸). On the other hand, in a case where 35 emitters are disposed in the laser diode, a yield rate of the laser diode is 70% (0.99³⁵).

Thus, according to the present exemplary embodiment, since a laser diode having a relatively short dimension in the array direction can be adopted as the laser diode, the yield rate of the laser diode can be improved.

The method for manufacturing light emitting device 120 will be described in more detail. The step (step S2) of disposing first beam twister unit 126A includes steps (step S23 and step S25) of adjusting and fixing the disposing position of first beam twister unit 126A, and the step (step S3) of disposing second beam twister unit 126B includes steps (step S33 and step S35) of adjusting and fixing the position of second beam twister unit 126B after first beam twister unit 126A is fixed.

As described above, since the plurality of beam twister units 126A and 126B are fixed one by one by adjusting the disposing positions, laser beams 101 and 102 from laser diodes 124A and 124 B are easily condensed.

In fact, first beam twister unit 126A and second beam twister unit 126B are disposed such that the plurality of first laser beams 101 emitted from first beam twister unit 126A and the plurality of second laser beams 102 emitted from second beam twister unit 126B are directed to the same position.

Thus, the condensing properties of the plurality of laser beams 101 and 102 from the plurality of laser diodes 124A and 124B can be enhanced, and the beam quality can be improved.

In the present exemplary embodiment, first beam twister unit 126A includes FAC lens 127 that adjusts the divergence angle of the plurality of first laser beams 101 in the fast direction, and second beam twister unit 126B includes FAC lens 127 that adjusts the divergence angle of the plurality of second laser beams 102 in the fast direction. In addition, both the magnitude of the warpage of first laser diode 124A and the magnitude of the warpage of second laser diode 124B are less than or equal to 3.0 μm, and the focal length of FAC lens 127 of each of beam twister units 126A and 126B is more than or equal to 30 μm and less than or equal to 50 μm.

Since the dimensions of laser diodes 124A and 124B in the array direction can be relatively shortened, the magnitude of the warpage thereof can be easily suppressed to be less than or equal to 3.0 μm accordingly. In addition, the focal length of FAC lens 127 of each of beam twister units 126A and 126B is more than or equal to 30 μm and less than or equal to 50 μm. Thus, laser beams 101 and 102 can be appropriately incident on beam twister lenses 128 of beam twister units 126A and 126B, respectively.

The method for manufacturing light emitting device 120 according to the present exemplary embodiment further includes a step (step S100) of cutting out first laser diode 124A and second laser diode 124B from the semiconductor wafer such that the dimensions of the plurality of emitters 180 of first laser diode 124A and second laser diode 124B in the array direction become predetermined dimension X0. When Y is a quotient obtained by dividing a dimension of a moiety to be cut out of the semiconductor wafer by an integer N of 4 or more, predetermined dimension X0 satisfies a relational expression of Y≥X0≥0.8 Y.

The obtainable number of laser diodes 124A and 124B varies depending on the setting of the dimensions of laser diodes 124A and 124B in the array direction with respect to the dimension of the semiconductor wafer. In addition, the obtainable number varies depending on a gap between the exposure ranges of the stepper exposure used in a procedure of manufacturing the semiconductor wafer.

In the present exemplary embodiment, since predetermined dimension X0 is set to Y≥X0≥0.8 Y, the obtainable number of semiconductor wafers can be increased while the gap between the exposure ranges of the stepper exposure is considered. That is, a residual moiety of the semiconductor wafer can be reduced as much as possible, and the semiconductor wafer can be effectively used.

Laser processing system 100 according to the present exemplary embodiment includes light emitting device 120. Thus, as described above, the beam quality of output light 104 of laser processing system 100 can be improved, and the light output of output light 104 can be improved.

### Second Exemplary Embodiment

Hereinafter, a second exemplary embodiment will be described mainly for differences from the first exemplary embodiment.

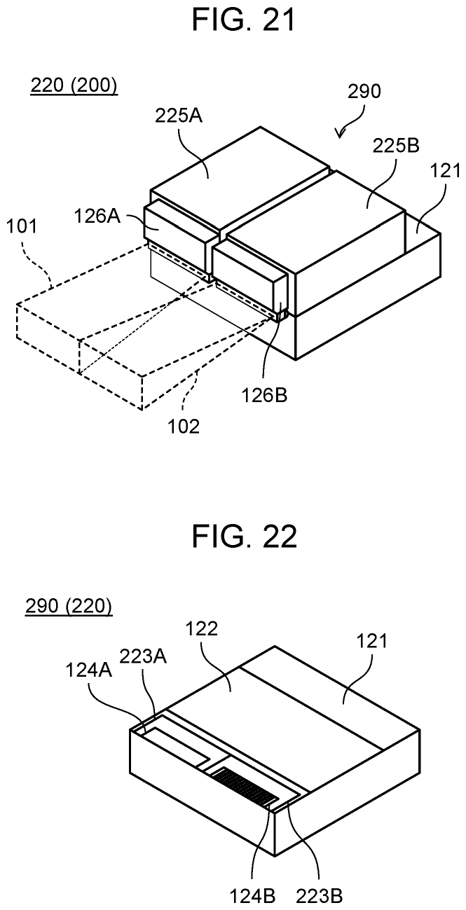

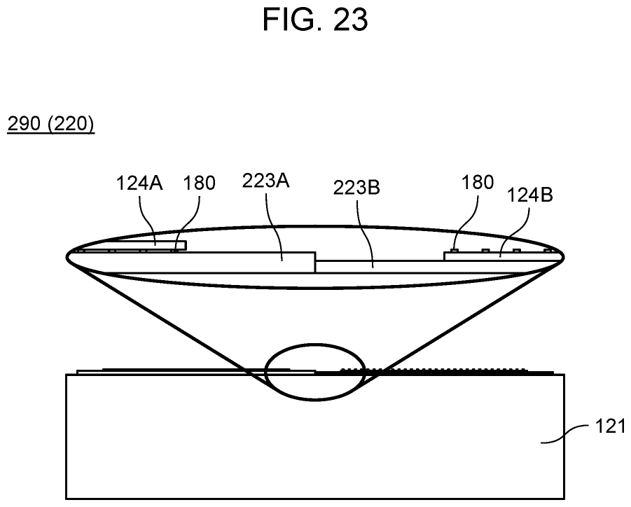

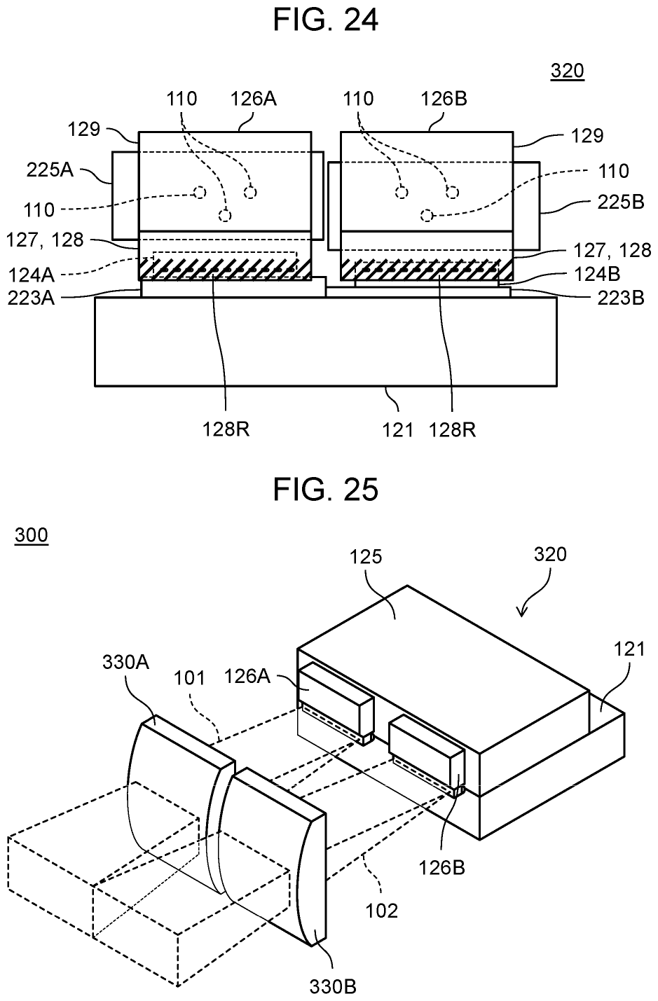

FIG. 21 is a schematic view illustrating light emitting device 220 included in laser processing system 200 according to the second exemplary embodiment. FIG. 22 is a schematic view illustrating light emitting device 220 when upper electrode 125 and beam twister units 126A and 126B are removed. FIG. 23 is a schematic view of light emitting device 220 excluding upper electrode 125 and beam twister units 126A and 126B as viewed from a front surface. FIG. 24 is a schematic view of light emitting device 220 as viewed from a front surface.

Laser processing system 200 according to the second exemplary embodiment includes light emitting device 220 instead of light emitting device 120. As illustrated in FIG. 21, light emitting device 220 includes LD module 290, first beam twister unit 126A, and second beam twister unit 126B.

LD module 290 includes lower electrode 121, insulating sheet 122, first laser diode 124A, and second laser diode 124 B.

In addition, LD module 290 includes first sub-mount 223A and second sub-mount 223B instead of first sub-mount 123A and second sub-mount 123B.

First sub-mount 223A and second sub-mount 223B are members different from each other, and are disposed on lower electrode 121. A thickness of first sub-mount 223A is different from a thickness of second sub-mount 223B, and FIGS. 23 and 24 illustrate that first sub-mount 223A is thicker than second sub-mount 223B.

First laser diode 124A is disposed on first sub-mount 223A such that a p-side faces lower electrode 121. On the other hand, second laser diode 124B is disposed on second sub-mount 223B such that an n-side faces lower electrode 121. Thus, lower electrode 121 is electrically connected to the p-side of first laser diode 124A and the n-side of second laser diode 124B.

As described above, the thicknesses are set such that first sub-mount 223A is thicker than second sub-mount 223B, and laser emission layer 181 of first laser diode 124A and laser emission layer 181 of second laser diode 124B have the same height. In other words, when first laser diode 124A and second laser diode 124B are disposed on first sub-mount 223A and second sub-mount 223B, respectively, the plurality of laser emission points of first laser diode 124A and the plurality of laser emission points of second laser diode 124B have the same height.

LD module 290 includes first upper electrode 225A and second upper electrode 225B instead of upper electrode 125.

First upper electrode 225A is electrically connected to the n-side of first laser diode 124A. Second upper electrode 225B is electrically connected to the p-side of second laser diode 124B, and is disposed apart from first upper electrode 225A. Thus, first upper electrode 225A and second upper electrode 225B are electrically insulated from each other.

In LD module 290, in a case where a current flows between first upper electrode 225A and second upper electrode 225B, the current flows through second upper electrode 225B, second laser diode 124B, lower electrode 121, first laser diode 124A, and upper electrode 225 A in this order. That is, first laser diode 124A and second laser diode 124B are connected in series.

Hereinafter, a method for manufacturing light emitting device 220 according to the second exemplary embodiment will be described. The method for manufacturing light emitting device 120 according to the second exemplary embodiment includes step S100 described above. Further, the method for manufacturing light emitting device 220 includes step S600 (steps S601 to S603) instead of step S200 (steps S201 to S203), and includes step S700 instead of step S300.

First, step S600 will be described. The p-side of first laser diode 124A is bonded to first sub-mount 223A, and the n-side of second laser diode 124B is bonded to second sub-mount 223B (step S601).

Subsequently, laser diodes 124A and 124B are disposed and bonded on lower electrode 121 such that sub-mounts 223A and 223B are in contact with lower electrode 121 (step S602).

Insulating sheet 122 is bonded onto lower electrode 121 to form electrical connection portions such as bumps on laser diodes 124A and 124 B, and upper electrode 225A and second upper electrode 225B are bonded onto first laser diode 124A and second laser diode 124B, respectively (step S603).

Note that, step S700 is the same as step S300 described above except that the current flows between first upper electrode 225A and second upper electrode 225B during light emission of laser diodes 124A and 124B.

Light emitting device 220 according to the second exemplary embodiment includes upper electrode 225A, upper electrode 225B disposed apart from upper electrode 225A, and lower electrode 121 disposed apart from upper electrode 225A and upper electrode 225B. Upper electrode 225A is electrically connected to the n-side of first laser diode 124A, lower electrode 121 is electrically connected to the p-side of first laser diode 124A and the n-side of second laser diode 124B, and upper electrode 225B is electrically connected to the p-side of second laser diode 124B.

That is, in light emitting device 220, first laser diode 124A and second laser diode 124B are connected in series.

Hereinafter, an effect of connecting first laser diode 124A and second laser diode 124B in series will be described using a laser processing system including 10 light emitting devices as an example.

In a case where 35 emitters 180 are disposed in each of laser diodes 124A and 124B of light emitting device 120 according to the first exemplary embodiment, a current value and a voltage value required for outputting laser beams from light emitting device 120 are, for example, 88 A and 4.5 V. In this case, in order to emit output light 104 from laser processing system 100, a power supply capable of outputting a current value of 88 A and a voltage value of 45 V (4.5 V×10) is required.

On the other hand, in light emitting device 220 according to the second exemplary embodiment, since laser diodes 124A and 124B are connected in series with each other, a voltage value required for outputting the laser beam from light emitting device 220 is increased (9.0 V), but a required current value is relatively small. For example, in a case where laser diodes 124A and 124B have 35 emitters 180, the required current value is 44 A.

Thus, in a case where the laser processing system includes light emitting device 220 according to the second exemplary embodiment, a power supply capable of outputting a current value of 44 A and a voltage value of 90 V (9.0 V×10) is required in order to emit output light from the laser processing system.

That is, according to the second exemplary embodiment, although a power value required for the power supply to output laser beams 101 and 102 is the same as a power value of the first exemplary embodiment, since a current value required for the power supply is small, a power supply circuit can be easily assembled in the laser processing system.

In addition, in the second exemplary embodiment, first laser diode 124A is disposed such that the p-side faces lower electrode 121, second laser diode 124B is disposed such that the n-side faces lower electrode 121, and laser emission layer 181 of second laser diode 124B is disposed at the same height as laser emission layer 181 of first laser diode 124A.

Specifically, light emitting device 220 includes first sub-mount 223A disposed on lower electrode 121 and second sub-mount 223B disposed on lower electrode 121 and different from first sub-mount 223A, first laser diode 124A is disposed on first sub-mount 223A, second laser diode 124B is disposed on second sub-mount 223B, and a thickness of first sub-mount 223A is different from a thickness of second sub-mount 223B.

As a result, the heights of laser emission layers 181 of laser diodes 124A and 124B arranged in orientations vertically opposite to each other can be uniform. Thus, since the heights of the optical axes of laser beams 101 and 102 emitted from laser diodes 124A and 124B can be uniform, the condensing properties of laser beams 101 and 102 can be enhanced, and the beam quality can be improved.

### First Modification

Hereinafter, laser processing system 300 according to a first modification will be mainly described mainly for differences from the above-described first exemplary embodiment.

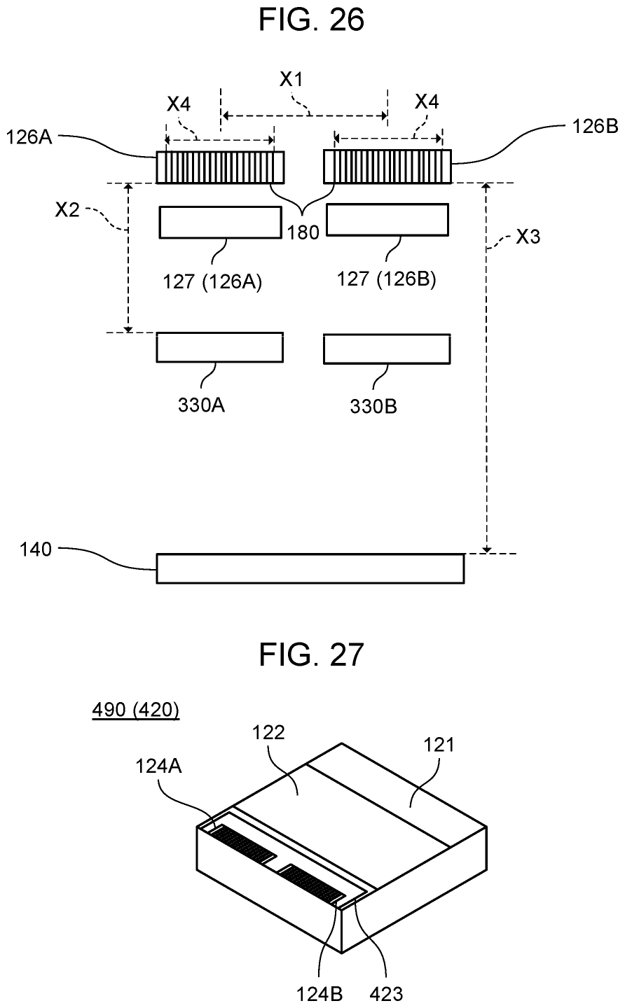

FIG. 25 is a diagram illustrating the vicinity of light emitting device 320 of laser processing system 300 according to the first modification. FIG. 26 is a diagram for describing a positional relationship between components in laser processing system 300. Note that, light emitting device 320 according to the first modification is the same in function and configuration as light emitting device 120 according to the first exemplary embodiment.

Laser processing system 100 according to the first exemplary embodiment includes one SAC lens 130. However, laser processing system 300 according to the present modification includes first SAC lens 330A and second SAC lens 330B. In laser processing system 300, optical components such as diffraction grating 140 and external resonance half mirror 170 are disposed on a downstream side of first laser beam 101 and second laser beam 102 in a traveling direction of first SAC lens 330A and second SAC lens 330B.

First SAC lens 330A and second SAC lens 330B are disposed to correspond to first laser diode 124A and second laser diode 124B, respectively.

The plurality of first laser beams 101 emitted from first beam twister unit 126A are transmitted through first SAC lens 330A. At that time, the plurality of first laser beams 101 are converged in a slow direction. In addition, the plurality of second laser beams 102 emitted from second beam twister unit 126B are transmitted through second SAC lens 330B. At that time, the plurality of second laser beams 102 are converged in the slow direction.

In laser processing system 300 according to the present modification, distance X1 from a center position between emission points at both ends of first laser diode 124A to a center position between emission points at both ends of second laser diode 124B satisfies Relational Expression (1).

$$X 1 \geq X 4 \times X 3 / ( X 3 - X 2 ) \qquad ( 1 )$$

Here, X2 is a focal length of SAC lens 330A, 330B, X3 is a distance from first laser diode 124A to diffraction grating 140, and X4 is a dimension between the emission points at both ends of first laser diode 124A and a dimension between the emission points at both ends of second laser diode 124B.

In other words, first laser diode 124A, second laser diode 124B, first SAC lens 330A, second SAC lens 330B, and diffraction grating 140 are disposed such that Relational Expression (1) is satisfied.

In addition, the method for manufacturing light emitting device 320 according to the present first modification includes steps S100 to S300 as in the first exemplary embodiment.

Hereinafter, a method for manufacturing laser processing system 300 according to the present modification will be described.

The method for manufacturing laser processing system 300 according to the present modification includes step S800 of disposing light emitting device 320 and step S900 of disposing the optical component. Note that, step S800 corresponds to step S400 described above.

Step S900 includes steps S901 to S903. First, in step S901, first SAC lens 330A and second SAC lens 330B are disposed. Hereinafter, step S901 will be described in detail.

First, first SAC lens 330A and second SAC lens 330B are disposed on a laser emission surface side of first beam twister unit 126A and second beam twister unit 126B, respectively. Next, a measurement camera (not illustrated) is disposed at a position where external resonance half mirror 170 is to be disposed. Further, a measurement camera (not illustrated) measures combined light of first laser beam 101 emitted from first SAC lens 330A and second laser beam 102 emitted from second SAC lens 330B. Disposing positions of first SAC lens 330A and second SAC lens 330B are adjusted such that a beam shape of the combined light is minimized in the slow direction.

Subsequently, in step S902, diffraction grating 140 is disposed on a downstream side of first SAC lens 330A and second SAC lens 330B in the traveling direction of laser beams 101 and 102.

Subsequently, in step S903, the remaining optical component such as external resonance half mirror 170 is disposed.

Through the above steps, laser processing system 300 according to the present modification is manufactured.

Note that, in the present modification, in steps S100, S200, and S300 in the method for manufacturing light emitting device 320, and in step S800 and step S900 in the method for manufacturing laser processing system 300, first laser diode 124A, second laser diode 124B, first SAC lens 330A, second SAC lens 330B, and diffraction grating 140 are disposed such that Relational Expression (1) described above is satisfied.

For example, in step S202 which is a part of step S200, laser diodes 124A and 124B are disposed apart from each other such that distance X1 satisfies Relational Expression (1) described above. This is because focal length X2 of SAC lens 330A, 330B and distance X3 from first laser diode 124A to diffraction grating 140 are determined in advance and dimension X4 of the dimension between the emission points at both ends of first laser diode 124A and the dimension between the emission points at both ends of second laser diode 124B are also determined in advance.

Laser processing system 300 according to the present modification includes first SAC lens 330A that adjusts a divergence angle of the plurality of first laser beams 101 emitted from first beam twister unit 126A in the slow direction, and second SAC lens 330B that is a lens different from first SAC lens 330A and adjusts a divergence angle of the plurality of second laser beams 102 emitted from second beam twister unit 126B in the slow direction.

The method for manufacturing laser processing system 300 according to the present modification includes a step (step S800) of disposing light emitting device 320, and a step (step S901) of disposing first SAC lens 330A that converges the plurality of first laser beams 101 emitted from first beam twister unit 126A in the slow direction and second SAC lens 330B that is a lens different from second SAC lens 330B and converges the plurality of second laser beams 102 emitted from second beam twister unit 126B in the slow direction.

In a case where there is an error in the disposing positions of laser diodes 124A and 124B in light emitting device 320, laser beams 101 and 102 from laser diodes 124A and 124B cannot be sufficiently condensed on diffraction grating 140 only by one SAC lens in some cases.

However, according to the present modification, since SAC lenses 330A and 330B are provided to correspond to laser diodes 124 and 124B, respectively, even though some errors occur in the disposing positions of laser diodes 124A and 124B, laser beams 101 and 102 can be adjusted by SAC lenses 330A and 330B, respectively, to enhance the condensing property on diffraction grating 140. As a result, the beam quality of the output light from laser processing system 300 can be increased.

In addition, laser processing system 300 further includes diffraction grating 140 disposed downstream of first SAC lens 330A and second SAC lens 330B in the traveling direction of first laser beam 101 and second laser beam 102.

When the focal length of first SAC lens 330A is X2, the distance from first laser diode 124A to diffraction grating 140 is X3, and the dimension between the emission points at both ends of first laser diode 124A is X4, first laser diode 124A and second laser diode 124B are disposed such that distance X1 from the center position between the emission points at both ends of first laser diode 124A to the center position between the emission points at both ends of second laser diode 124B satisfies Relational Expression (1) described above.

Correspondingly, the method for manufacturing laser processing system 300 includes a step (step S902) of disposing diffraction grating 140 on the downstream side of first SAC lens 330A and second SAC lens 330B in the traveling direction of first laser beam 101 and second laser beam 102. When the distance from the center position between the emission points at both ends of first laser diode 124A to the center position between the emission points at both ends of second laser diode 124B is X1, the focal length of first SAC lens 330A is X2, the distance from first laser diode 124A to diffraction grating 140 is X3, and the dimension between the emission points at both ends of first laser diode 124A is X4, first laser diode 124A, second laser diode 124B, first SAC lens 330A, and diffraction grating 140 are disposed to satisfy Relational Expression (1) described above.

As a result, the plurality of first laser beams 101 emitted from first laser diode 124A can be incident on first SAC lens 330A without being incident on second SAC lens 330B. In addition, the plurality of second laser beams 102 emitted from second laser diode 124B can be incident on second SAC lens 330B without being incident on first SAC lens 330A.

Note that, in the first modification described above, light emitting device 320 has been described to be the same in function and configuration as light emitting device 120 according to the first exemplary embodiment, but may be the same in function and configuration as light emitting device 220 according to the second exemplary embodiment.

### Second Modification

Hereinafter, differences from the above-described first exemplary embodiment will be mainly described for a laser processing system and light emitting device 420 according to a second modification. FIG. 27 is a schematic view illustrating light emitting device 420 according to the second modification, and is a diagram illustrating light emitting device 420 when an upper electrode and a beam twister unit are removed.

A laser processing system (not illustrated) according to the second modification includes light emitting device 420 including LD module 490, and LD module 490 includes single sub-mount 423. That is, laser diodes 124A and 124B are bonded onto single sub-mount 423.

The method for manufacturing light emitting device 420 according to the present modification is the same as the method for manufacturing light emitting device 120 of the first exemplary embodiment except that laser diodes 124A and 124B are bonded to single sub-mount 423.

According to the second modification, effects similar to the effects of the above-described first exemplary embodiment can be obtained.

Note that, similarly to light emitting device 220 according to the second exemplary embodiment, light emitting device 420 may be disposed such that the p-side of first laser diode 124A faces lower electrode 121 and the n-side of second laser diode 124B faces lower electrode 121.

In this case, a step is provided in sub-mount 423, and first laser diode 124A is disposed at a higher position than second laser diode 124B in sub-mount 423. As a result, since laser emission layer 181 of first laser diode 124A and laser emission layer 181 of second laser diode 124B are disposed to have the same height, the plurality of laser emission points of first laser diode 124A and the plurality of laser emission points of second laser diode 124B have the same height.

In addition, light emitting device 420 includes first upper electrode connected to the n-side of first laser diode 124A, and a second upper electrode disposed apart from the first upper electrode to be electrically insulated from the first upper electrode, and connected to the p-side of second laser diode 124B.

As described above, in light emitting device 420, since the p-side of first laser diode 124A faces lower electrode 121, the n-side of second laser diode 124B faces lower electrode 121, and the laser emission points of laser diodes 124A and 124B are disposed at the same height, functions and effects as the functions and effects of the second exemplary embodiment can be obtained.

### Other Modifications

In each of the above-described exemplary embodiments and modifications, although two laser diodes are mounted on one light emitting device, three or more laser diodes may be mounted on one light emitting device.

In addition, in the second exemplary embodiment and the modifications, it has been described that the p-side of first laser diode 124A faces lower electrode 121 and the n-side of second laser diode 124B faces lower electrode 121, the n-side of first laser diode 124A may face lower electrode 121 and the p-side of second laser diode 124B may face lower electrode 121.

In addition, in the laser processing system according to each exemplary embodiment and each modification described above, a plurality of light emitting devices may be mounted.

According to the present disclosure, it is possible to provide a light emitting device, a laser processing system, a method for manufacturing a light emitting device, and a method for manufacturing a laser processing system capable of improving beam quality.

### INDUSTRIAL APPLICABILITY

The light emitting device, the laser processing system, the method for manufacturing a light emitting device, and the method for manufacturing a laser processing system of the present disclosure are suitable for a wavelength beam combining semiconductor laser processing device.

### REFERENCE MARKS IN THE DRAWINGS

1: laser beam
2: combined light
3: output light
10: laser processing system
20: light emitting device
21: lower electrode
22: insulating sheet
23: sub-mount
24A: first laser diode
24B: second laser diode
25: upper electrode
26: beam twister unit
27: FAC lens
28: beam twister lens
29: holding block
30: SAC lens
40: diffraction grating
50: convex lens
60: concave lens
70: external resonance half mirror
80: emitter
81: laser emission layer
82: p-side electrode
83: n-side electrode
90: laser diode module
100: laser processing system
101: first laser beam
102: second laser beam
104: output light
106: ultraviolet ray
110: adhesive
120: light emitting device
121: lower electrode
122: insulating sheet
123A: first sub-mount
123B: second sub-mount
124A: first laser diode
124B: second laser diode
125: upper electrode
126A: first beam twister unit
126B: second beam twister unit
127: FAC lens
128: beam twister lens
129: holding block
130: SAC lens
140: diffraction grating
150: convex lens
160: concave lens
170: external resonance half mirror
180: emitter
181: laser emission layer
182: p-side electrode
183: n-side electrode
190: laser diode module
200: laser processing system
220: light emitting device
223A: first sub-mount
223B: second sub-mount
225A: first upper electrode
225B: second upper electrode
290: laser diode module
300: laser processing system
320: light emitting device
330A: first SAC lens
330B: second SAC lens
400: laser processing system
420: light emitting device
423: sub-mount
BS1: beam spot
BS2: beam spot
CL1: optical axis
CL2: optical axis
P1: Intensity distribution
P2: Intensity distribution
P3: Intensity distribution

1. A light emitting device comprising:
a first laser diode including a plurality of emitters that emit first laser beams;
a second laser diode including a plurality of emitters that emit second laser beams, the second laser diode being different from the first laser diode;
a first beam twister unit provided to correspond to the first laser diode; and
a second beam twister unit provided to correspond to the second laser diode, the second beam twister unit being different from the first beam twister unit.

2. The light emitting device according to claim 1, further comprising:
a first electrode;
a second electrode disposed apart from the first electrode; and
a third electrode disposed apart from the first electrode and the second electrode, wherein
the first electrode is electrically connected to an n-side of the first laser diode,
the third electrode is electrically connected to a p-side of the first laser diode and an n-side of the second laser diode, and
the second electrode is electrically connected to a p-side of the second laser diode.

3. The light emitting device according to claim 2, wherein
the first laser diode includes a first laser emission layer including the plurality of emitters,
the second laser diode includes a second laser emission layer including the plurality of emitters,
in the first laser diode, the p-side of the first laser diode faces the third electrode, and
in the second laser diode, the n-side of the second laser diode faces the third electrode and the second laser emission layer has a same height as the first laser emission layer.

4. The light emitting device according to claim 3, further comprising:
a first sub-mount disposed on the third electrode; and
a second sub-mount disposed on the third electrode, the second sub-mount being different from the first sub-mount, wherein
the first laser diode is disposed on the first sub-mount,
the second laser diode is disposed on the second sub-mount, and
a thickness of the first sub-mount is different from a thickness of the second sub-mount.

5. The light emitting device according to claim 1, wherein the first beam twister unit and the second beam twister unit are disposed so that the first laser beams emitted from the first beam twister unit and the second laser beams emitted from the second beam twister unit are directed to a same position.

6. The light emitting device according to claim 1, wherein
the first beam twister unit includes a first FAC (Fact Axis Collimation) lens that adjusts a divergence angle of the first laser beams in a fast direction,
the second beam twister unit includes a second FAC lens that adjusts a divergence angle of the second laser beams in the fast direction,
both magnitudes of warpage of the first laser diode and warpage of the second laser diode are less than or equal to 3.0 μm, and
both focal lengths of the first FAC lens and the second FAC lens are more than or equal to 30 μm and less than or equal to 50 μm.

7. A laser processing system comprising the light emitting device according to claim 1.

8. The laser processing system according to claim 7, further comprising:
a first SAC (Slow Axis Collimation) lens that adjusts a divergence angle of the first laser beams emitted from the first beam twister unit in a slow direction; and
a second SAC lens that adjusts a divergence angle of the second laser beams emitted from the second beam twister unit in the slow direction, the second SAC lens being different from the first SAC lens.

9. The laser processing system according to claim 8, further comprising a diffraction grating disposed on a downstream side of the first SAC lens and the second SAC lens in a traveling direction of the first laser beams and the second laser beams,
wherein, when a focal length of the first SAC lens is X2, a distance from the first laser diode to the diffraction grating is X3, and a dimension between emission points at both ends of the first laser diode is X4, in the first laser diode and the second laser diode, a distance X1 from a center position between the emission points at both the ends of the first laser diode to a center position between emission points at both ends of the second laser diode satisfies a relational expression expressed by X1≥X4×X3/(X3−X2).

10. A method for manufacturing a light emitting device, comprising:
disposing a first laser diode including a plurality of emitters that emit first laser beams;
disposing a second laser diode including a plurality of emitters that emit second laser beams, the second laser diode being different from the first laser diode;
disposing a first beam twister unit to correspond to the first laser diode; and
disposing a second beam twister unit different from the first beam twister unit to correspond to the second laser diode.

11. The method for manufacturing a light emitting device according to claim 10, wherein
the disposing of the first beam twister unit includes adjusting and fixing a disposing position of the first beam twister unit, and
the disposing of the second beam twister unit includes adjusting and fixing a position of the second beam twister unit after the first beam twister unit is fixed.

12. The method for manufacturing a light emitting device according to claim 10, further comprising cutting out the first laser diode and the second laser diode from a semiconductor wafer, dimensions of the plurality of emitters of the first laser diode and the second laser diode in an array direction becoming a predetermined dimension X0,
wherein, when Y is a quotient obtained by dividing a dimension of a portion to be cut out of the semiconductor wafer by an integer N of 4 or more, the predetermined dimension X0 satisfies a relational expression of Y≥X0≥0.8 Y.

13. A method for manufacturing a laser processing system, comprising:
disposing the light emitting device according to claim 1; and
disposing a first SAC lens that adjusts a divergence angle of the first laser beams emitted from the first beam twister unit in a slow direction and a second SAC lens that adjusts a divergence angle of the second laser beams emitted from the second beam twister unit in the slow direction, the second SAC lens being different from the first SAC lens.

14. The method for manufacturing a laser processing system according to claim 13, further comprising disposing a diffraction grating on a downstream side of the first SAC lens and the second SAC lens in a traveling direction of the first laser beams and the second laser beams,
wherein, when a distance from a center position between emission points at both ends of the first laser diode to a center position between emission points at both ends of the second laser diode is X1, a focal length of the first SAC lens is X2, a distance from the first laser diode to the diffraction grating is X3, and a dimension between the emission points at both the ends of the first laser diode is X4, the first laser diode, the second laser diode, the first SAC lens, and the diffraction grating are disposed to satisfy a relational expression expressed by X1≥X4×X3/(X3−X2).
